(19) United States
(12) Patent Application Publication
(10) Pub. No.: US 2026/0215219 A1
(43) Pub. Date: Jul. 23, 2026

(54) BONDING APPARATUS, BONDING METHOD, AND ARTICLE MANUFACTURING METHOD

(71) Applicant: CANON KABUSHIKI KAISHA, Tokyo (JP)

(72) Inventors: MAKOTO NAKAGOMI, Tochigi (JP); MASAHIRO KIMURA, Tochigi (JP); KAZUHIKO MISHIMA, Tochigi (JP)

(21) Appl. No.: 19/434,252

(22) Filed: Dec. 29, 2025

(30) Foreign Application Priority Data
Jan. 20, 2025 (JP) 2025-007982

(51) Int. Cl. H10P 72/50; B32B 37/12; B32B 38/18; B32B 41/00; H10P 72/00

(52) U.S. Cl. CPC H10P 72/53; B32B 37/12; B32B 38/1833; B32B 41/00; H10P 72/0438; B32B 2457/14

(57) ABSTRACT

A bonding apparatus for bonding a second member to a first member, includes a first holder configured to hold the first member, a second holder configured to hold the second member, a positioning mechanism configured to adjust a relative position between the first holder and the second holder, a first camera configured to capture the first member, a second camera held by the first holder and configured to capture the second member, and a controller configured to control, based on an output of the first camera, an output of the second camera, and an operation history of the bonding apparatus, the positioning mechanism so as to position the second member to a bonding target location of the first member.

### BACKGROUND

### Field of the Technology

The present disclosure relates to a bonding apparatus, a bonding method, and an article manufacturing method.

### Description of the Related Art

Japanese Patent Laid-Open No. 2023-77928 describes a bonding apparatus for bonding a second member (second object) to a first member (first object). This bonding apparatus includes a first holder that holds the first member, a second holder that holds the second member, a positioning mechanism that changes a relative position between the first holder and the second holder, a first camera that captures the first member, and a second camera that captures the second member. The bonding apparatus also includes a controller that controls, based on the output of the first camera and the output of the second camera, the positioning mechanism so as to position the second member to a bonding target location of the first member.

In a case where the second camera is held by the first holder that holds the first member, when the first holder deforms due to heat, an error occurs in the measurement result of the position of the second member by the second camera, and thus the alignment accuracy between the first member and the second member may degrade. If the relative position between the first camera and the second camera is often measured to prevent the alignment accuracy from degrading, productivity may decrease.

### SUMMARY

The present disclosure provides a technique advantageous in suppressing degradation of alignment accuracy between a first member and a second member and degradation of productivity in a bonding apparatus that bonds the second member to the first member.

The present disclosure includes a bonding apparatus for bonding a second member to a first member, comprising: a first holder configured to hold the first member; a second holder configured to hold the second member; a positioning mechanism configured to adjust a relative position between the first holder and the second holder; a first camera configured to capture the first member; a second camera held by the first holder and configured to capture the second member; and a controller configured to control, based on an output of the first camera, an output of the second camera, and an operation history of the bonding apparatus, the positioning mechanism so as to position the second member to a bonding target location of the first member.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the configuration of a bonding apparatus according to an embodiment;

FIG. 2 is a view schematically showing the configuration of a substrate stage;

FIG. 3 is a view schematically showing a bonding method;

FIG. 4 is a flowchart illustrating the procedure of the bonding method in the bonding apparatus;

FIGS. 5A and 5B are timing charts each visually showing a characteristic formula that gives a correction amount;

FIG. 6 is a view exemplifying movement of a substrate stage;

FIG. 7 is a timing chart exemplifying a change of a correction amount caused by the stop of a substrate stage; and

FIG. 8 is a timing chart exemplifying the relationship between a change of the power supply state of a die observation camera and a change of the temperature of the die observation camera.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

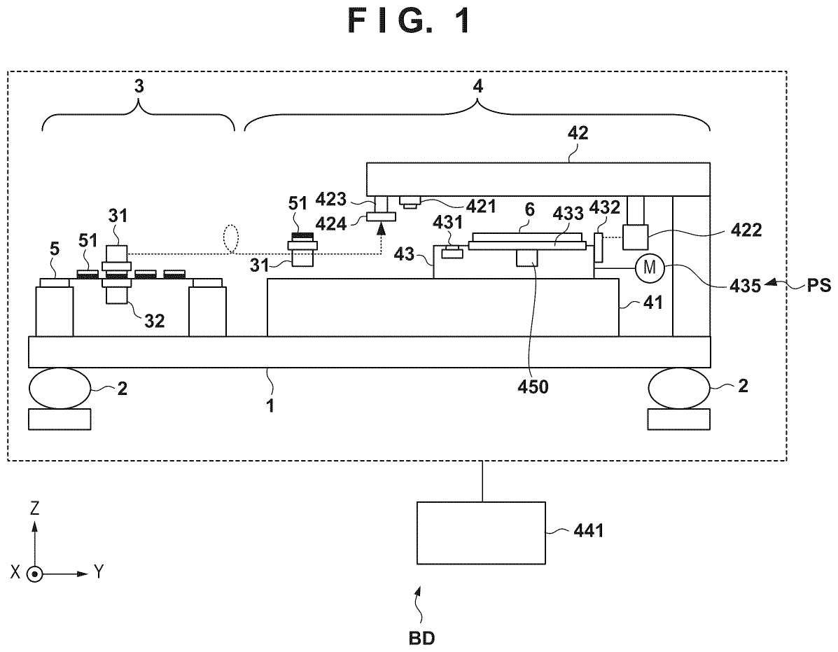

FIG. 1 is a view schematically showing the configuration of a bonding apparatus BD according to the first embodiment. The bonding apparatus BD bonds a second member to a first member. In the specification and the accompanying drawings, directions will be indicated on an XYZ coordinate system in which a horizontal surface is defined as the X-Y plane. Generally, a substrate 6 serving as the first member can be placed on a substrate stage 43 serving as a first holder so that the surface of the substrate 6 becomes parallel to the horizontal surface (X-Y plane), and held by the substrate stage 43. In the following description, directions orthogonal to each other within a plane along the surface of the substrate 6 held by the substrate stage 43 will be defined as the X-axis and the Y-axis, and a direction perpendicular to the X-axis and the Y-axis will be defined as the Z-axis. In addition, in the following description, directions parallel to the X-axis, the Y-axis, and the Z-axis in the XYZ coordinate system will be referred to as the X direction, the Y direction, and the Z direction, respectively.

In the specification and the accompanying drawings, a suffix attached to a reference numeral is used to indicate a specific one of those represented by the reference numeral. For example, the bonding apparatus BD shown in FIG. 1 can include a bar mirror 432 serving as a measured portion, as will be described later. The bar mirror 432 can include direction-specific bar mirrors 432a and 432b (see FIG. 2), as exemplified in FIG. 2. When a direction-specific bar mirror needs to be specified, a reference numeral with a suffix such as the bar mirror 432a or the bar mirror 432b is used. In contrast, when a bar mirror need not be specified, a reference numeral without a suffix such as the bar mirror 432 is used.

The first member may be a substrate (wafer) on which semiconductor devices are formed, and the second member may be a die on which a semiconductor device is formed and individually divided, but the first and second members are not limited to them. For example, the second member can be a silicon interposer obtained by forming wiring paths on a silicon substrate, a glass interposer obtained by forming wiring paths on a glass substrate, or an organic interposer obtained by forming wiring paths on an organic panel (PCB). Alternatively, the second member may be an object obtained by bonding, to a substrate on which a semiconductor device is formed, a die on which some semiconductor devices have already been formed. Alternatively, the second member may be a stack of dies that have already been individually divided, a small piece of a material, an optical element, a MEMS, a structure, or the like.

The present disclosure does not limit the bonding method of the first and second members to a specific bonding method. For example, an arbitrary bonding method may be employed, including bonding using an adhesive, temporary bonding using a temporary adhesive, bonding by hybrid bonding, atomic diffusion bonding, vacuum bonding, and bump bonding. Various temporary bonding and permanent bonding methods are available.

Industrial application examples of the bonding apparatus in the present disclosure will be explained below.

The first application example is manufacturing of a stacked memory. In a case where the bonding apparatus is applied to manufacturing of a stacked memory, the second member can be an individually divided memory die, and the first member can be a substrate on which a memory serving as a semiconductor device is manufactured. For example, in bonding of the eighth layer in a case where eight layers are stacked, the first member is a substrate on which a six-layered memory die has already been bonded to a substrate. Note that the top layer is sometimes a driver die that drives the memory.

The second application example is heterogeneous integration of a processor. The mainstream of conventional processors is a SoC in which a logic circuit and an SRAM are formed in one semiconductor element. To the contrary, in heterogeneous integration, elements are manufactured on separate substrates by applying processes optimal for the respective elements, and are bonded, thereby manufacturing a processor. This can implement cost reduction and yield improvement of processors. In a case where the bonding apparatus is applied to heterogeneous integration, the second member can be a die individually divided after probing, such as an SRAM, an antenna, or a driver, and the first member can be a substrate on which a memory serving as a semiconductor device is manufactured. In general, different dies are sequentially bonded to a substrate. For example, in bonding the next die of an SRAM in the case of bonding from an SRAM, the first member is a logic substrate to which an SRAM die is bonded.

The third application example is 2.5D bonding using a silicon interposer. The silicon interposer is a silicon wafer on which wiring paths are formed. The 2.5D bonding is a method of bonding individually divided dies using the silicon interposer, and electrically bonding the dies. In a case where the bonding apparatus is applied to die bonding of a silicon interposer, the first member can be an individually divided die, and the second member can be a silicon interposer obtained by forming wiring paths on a silicon wafer. Generally, a plurality of types of dies are bonded to a silicon interposer, so the second member includes a silicon interposer to which some dies have already been bonded.

The fourth application example is 2.1D bonding using an organic interposer or a glass interposer. The organic interposer is an organic panel (a PCB substrate or a CCL substrate) used as a package substrate, on which wiring paths are formed. The glass interposer is a glass panel on which wiring paths are formed. The 2.1D bonding is a method of bonding individually divided dies to the organic interposer or the glass interposer, and electrically bonding the dies by the wiring paths on the interposer. In a case where the bonding apparatus is applied to die bonding to the organic interposer, the first member can be an organic panel on which wiring paths are formed, and the second member can be an individually divided die. In a case where the bonding apparatus is applied to die bonding of the glass interposer, the first member can be an individually divided die, and the second member can be a glass panel on which wiring paths are formed. In general, a plurality of types of dies are bonded to an organic interposer or a glass interposer, so the first member includes an organic interposer or a glass interposer to which some dies have already been bonded.

The fifth application example is heterogeneous substrate bonding. For example, in an infrared image sensor, InGaAs is known as a high-sensitivity material. There has been proposed a method of manufacturing a high-sensitivity high-speed infrared image sensor using InGaAs for a sensor unit that receives light, and using silicon capable of forming a high-speed processing die for a logic circuit that extracts data. However, for InGaAs crystal, only substrates whose diameter is as small as 4 inches are mass-produced, which is smaller than a mainstream 300-mm silicon wafer. Hence, there has been proposed a method of bonding an individually divided InGaAs substrate onto a 300-mm silicon wafer on which a logic circuit is formed. In this manner, bonding of substrates different in material and size is called heterogeneous substrate bonding. In the application of the bonding apparatus to heterogeneous substrate bonding, the first member can be a substrate with a large diameter such as a silicon wafer, and the second member can be a small piece of a material such as InGaAs. Note that a small piece of a material is a slice of a crystal and is desirably cut into a rectangular shape.

In the following description, to provide a practical example, assume that the first member is a substrate (wafer) on which a semiconductor device is formed, and the second member is an individually divided die on which a semiconductor device is formed.

In an example shown in FIG. 1, a direction perpendicular to the sheet surface is defined as the X direction, a right direction on the sheet surface is defined as the Y direction, and an upper direction on the sheet surface is defined as the Z direction. The bonding apparatus BD can include a pickup unit 3 and a bonding unit 4 that are mounted on a base 1 damped by mounts 2. The bonding apparatus BD bonds, at an arbitrary position (bonding target location) on a substrate 6 serving as the first member, each individually divided die 51 serving as the second member aligned on a dicing tape adhered to a dicing frame 5. Note that the pickup unit 3 and the bonding unit 4 are mounted on the same base in the example of FIG. 1, but may be mounted on separate bases.

The pickup unit 3 can include a pickup head 31 and a release head 32. The release head 32 can peel the dicing tape from the die 51, and the pickup head 31 can hold, by vacuum suction or the like, the die 51 from which the dicing tape is peeled by the release head 32. The pickup head 31 can rotate about the Y-axis so that the held die 51 faces up, and transfer the die 51 to a bonding head 423 serving as the second holder. The bonding head 423 can be provided with a suction unit 424 configured to hold the die 51 by vacuum suction or the like.

The bonding unit 4 can include a stage base 41 and an upper base 42. The substrate stage 43 serving as the first holder can be mounted on the stage base 41. The substrate stage 43 can be driven in the X and Y directions and driven to rotate about the Z-axis by a driving mechanism 435. Note that the rotating operation need not always be executed by the substrate stage 43, and may be executed on the bonding head 423 side.

A die observation camera 431 serving as a second camera can be mounted on the substrate stage 43. The die observation camera 431 can be used to measure, for example, the position of a feature point of the die 51 serving as the second member, the outer dimensions of the die, and the distances of a plurality of points of the die in the direction of height. Therefore, by using the die observation camera 431, the position, outer dimensions, and flatness of the die held by the bonding head 423 can be measured.

The bar mirror 432 serving as a measured portion is arranged on the side surfaces of the substrate stage 43 serving as the first holder. The bar mirror 432 is the target of an interferometer 422. The interferometer 422 is an example of a measuring device that measures the position of the substrate stage 43. The interferometer 422 may be replaced by, for example, another measuring device such as an encoder. A substrate chuck 433 that holds the substrate 6 serving as the first member is mounted on the substrate stage 43. The substrate holding method of the substrate chuck 433 may be vacuum suction, electrostatic chucking, or another method.

The upper base 42 can support a substrate observation camera 421 serving as a first camera. The substrate observation camera 421 can be used to, for example, measure the position of a feature point on the substrate 6 and measure the flatness by measuring the distances of a plurality of points in the Z direction. The upper base 42 can function as a support that supports the interferometer 422 configured to measure the position of the substrate stage 43, and the bonding head 423 serving as the second holder that holds the die 51 serving as the second member transferred from the pickup head 31. The substrate observation camera 421 can use visible light or infrared light as a measurement light source. The substrate observation camera 421 can be configured to measure, for example, the position of a feature point such as a mark or an element pattern formed on or in the substrate 6.

A driving mechanism 450 can be configured to drive (Z-drive) the substrate chuck 433 in the Z direction in order to perform a bonding operation on the die 51 and the substrate 6. The driving mechanism 450 may be configured to Z-drive the substrate stage 43. The bonding operation can include an approximating operation of moving the bonding head 423 and the substrate chuck 433 close to each other so as to bring the die 51 and the substrate 6 into contact with each other, and a separating operation of moving the bonding head 423 and the substrate chuck 433 away from each other after the approximating operation. The driving mechanism 450 can perform the approximating operation by driving the substrate chuck 433 in the +Z direction, and perform the separating operation by driving the substrate chuck 433 in the-Z direction. Alternatively, the approximating operation may be performed by driving the bonding head 423 in the +Z direction, and the separating operation may be performed by driving the bonding head 423 in the-Z direction. Alternatively, the bonding operation may be performed by Z-driving both the bonding head 423 and the substrate chuck 433. That is, the driving mechanism 450 suffices to be a relative driving mechanism that relatively drives the bonding head 423 and the substrate chuck 433 so as to change the interval between the die 51 and the substrate 6. When the substrate chuck 433 is driven by such a relative driving mechanism, the position of the substrate chuck 433 in the Z direction is feedback-controlled in real time while measured by the interferometer 422.

In the above description, the pickup head 31 is configured to rotate and transfer the die 51 to the bonding head 423. However, it is also possible to provide two or more die holders, relay the die 51 between the die holders, and then transfer it to the bonding head 423. Alternatively, the bonding head 423 may be configured to receive the die 51 by the driving mechanism of the bonding head 423. To improve the productivity, a plurality of pickup units, a plurality of pickup heads, a plurality of release heads, and a plurality of bonding heads may be arranged.

A controller 441 comprehensively controls the respective components of the bonding apparatus BD. The controller 441 can control, for example, the operation of the driving mechanism 450 and the suction force (holding force) of the bonding head 423 (suction unit 424) to the die. The controller 441 can be constituted by a computer (information processing apparatus) including a processor such as a Central Processing Unit (CPU) and a storage such as a memory. Note that the controller 441 may be arranged inside the housing of the bonding apparatus BD or outside the housing. The controller 441 arranged outside the housing of the bonding apparatus BD may be implemented by, for example, a computer functioning as a control server connected to the main body of the bonding apparatus BD via a network.

FIG. 2 is a view of the substrate stage 43 when viewed in a positive direction about the Z-axis. The substrate 6 is held by the substrate chuck 433. The bar mirror 432 can include at least two bar mirrors so that positions of the substrate 6 in the X direction, the Y direction, and a rotational direction about the Z-axis can be measured. The bar mirror 432a serves as the target of an interferometer 422a that measures a position in the X direction, and that of an interferometer 422c that measures an amount of rotation about the Z-axis based on a difference from a measurement value of the interferometer 422a. The bar mirror 432b serves as the target of an interferometer 422b that measures a position in the Y direction. The interferometer 422 can measure in real time a position of the substrate stage 43 in the X direction, a position in the Y direction, and an amount of rotation about the Z-axis. The interferometer 422 and the driving mechanism 435 form a positioning mechanism PS that feedback-controls the substrate stage 43. The positioning mechanism PS can position the substrate stage 43 at high precision by feedback-controlling the substrate stage 43 in real time based on the result of measurement by the interferometer 422.

A reference plate 434 having a plurality of marks (including marks 434a, 434b, and 434c) is arranged beside the substrate chuck 433. The reference plate 434 desirably has a low thermal expansion coefficient and bears marks drawn at high positional precision. In an example, the reference plate 434 can be a quartz substrate on which marks are drawn using a drawing method in a semiconductor lithography process. It is desirable that the surface of the reference plate 434 is arranged at the same level as the surface of the substrate 6 and can be observed by the substrate observation camera 421. However, the reference plate 434 is not limited to this when a camera is separately constituted to observe the reference plate 434. The substrate stage 43 can include a coarse moving stage capable of driving in a large range, and a fine moving stage arranged on the coarse moving stage and capable of driving in a small range at high precision. In this case, the die observation camera 431, the bar mirror 432, the substrate chuck 433, and the reference plate 434 can be fixed on the fine moving stage to perform high-precision positioning.

A method of guaranteeing the origin position, magnification, X-and Y-axis directions (rotations), and orthogonality of the substrate stage 43 using the reference plate 434 will be explained. The mark 434a can be captured by the substrate observation camera 421, and a measurement value of the interferometer 422 when the mark 434a is located at the center of an image captured by the substrate observation camera 421 can be defined as the origin of the substrate stage 43. Then, the mark 434b can be captured by the substrate observation camera 421, and the Y-axis direction and Y magnification of the substrate stage 43 can be decided from a measurement value of the interferometer 422 when the mark 434b is located at the center of an image captured by the substrate observation camera 421. Further, the mark 434c can be captured by the substrate observation camera 421, and the X-axis direction and X magnification of the substrate stage 43 can be decided from a measurement value of the interferometer 422 when the mark 434c is located at the center of an image captured by the substrate observation camera 421.

That is, a direction from the mark 434b of the reference plate 434 toward the mark 434a is defined as the Y direction, a direction from the mark 434c toward the mark 434a is defined as the X direction, and then calibration of the axial direction and the orthogonality can be performed. In addition, the interval between the mark 434b and the mark 434a is defined as a scale reference in the Y direction, the interval between the mark 434c and the mark 434a is defined as a scale reference in the X direction, and then calibration can be performed. The measurement value of the interferometer varies upon a change of the refractive index of the optical path of the interferometer due to pressure variations and temperature variations. Thus, calibration is desirably performed at an arbitrary timing to guarantee the origin position, magnification, rotation, and orthogonality of the substrate stage 43. Note that the temperature in the space of the substrate stage is desirably controlled by a temperature-regulated chamber in order to reduce variations of the measurement value of the interferometer. On the substrate stage 43, the die observation camera 431 is arranged at a position apart from both the bar mirror 432 and the reference plate 434. When the die observation camera 431 or the substrate stage 43 deforms due to heat, an error occurs in the measurement result of the position of the die 51 measured using the die observation camera 431.

Instead of performing calibration using the reference plate 434, for example, calibration may be performed by an abutment operation of the substrate stage 43 against the reference surface. Alternatively, high-precision positioning may be performed using a position measurement unit in which an absolute value is guaranteed, such as a white interferometer.

The controller 441 can execute obtaining processing of obtaining a characteristic formula representing the relationship between the operation history of the bonding apparatus BD and the change amount of the relative position between the reference plate 434 and the die observation camera 431 (second camera). In this obtaining processing, the controller 441 can obtain the relative position between the reference plate 434 and the die observation camera 431 by capturing at least one mark 434 of the reference plate 434 and a feature point of the die observation camera 431 by the substrate observation camera 421. More specifically, the controller 441 can obtain a characteristic formula by obtaining the relative position between the reference plate 434 and the die observation camera 431 and the operation state of the bonding apparatus BD at each of a plurality of times, and recording the relative position and the operation state.

For example, assume that the measurement value of the position of the substrate stage 43 obtained by the interferometer 422 when the center of the mark 434 of the reference plate 434 is made to match the center of the field of view of the substrate observation camera 421 is defined as a first measurement value. Assume also that the measurement value of the position of the substrate stage 43 obtained by the interferometer 422 when the feature point (for example, the mark) of the die observation camera 431 is made to match the center of the field of view of the substrate observation camera 421 is defined as a second measurement value. The controller 441 can obtain, as the relative position between the reference plate 434 and the die observation camera 431, the difference between the first measurement value and the second measurement value. The change amount of the relative position between the reference plate 434 and the die observation camera 431 based on the operation history of the bonding apparatus BD can be regarded as the change amount of the position of the die observation camera 431 based on the operation history of the bonding apparatus BD. The change amount of the position of the die observation camera 431 based on the operation history of the bonding apparatus BD can be caused by, for example, deformation of the die observation camera 431 due to heat generated by the die observation camera 431. Alternatively, the change amount of the position of the die observation camera 431 based on the operation history of the bonding apparatus BD can be caused by deformation of the substrate stage 43 due to heat generated by the die observation camera 431. Alternatively, the change amount of the position of the die observation camera 431 based on the operation history of the bonding apparatus BD can be caused by deformation of the substrate stage 43 due to heat generated by the positioning mechanism PS that drives the substrate stage 43.

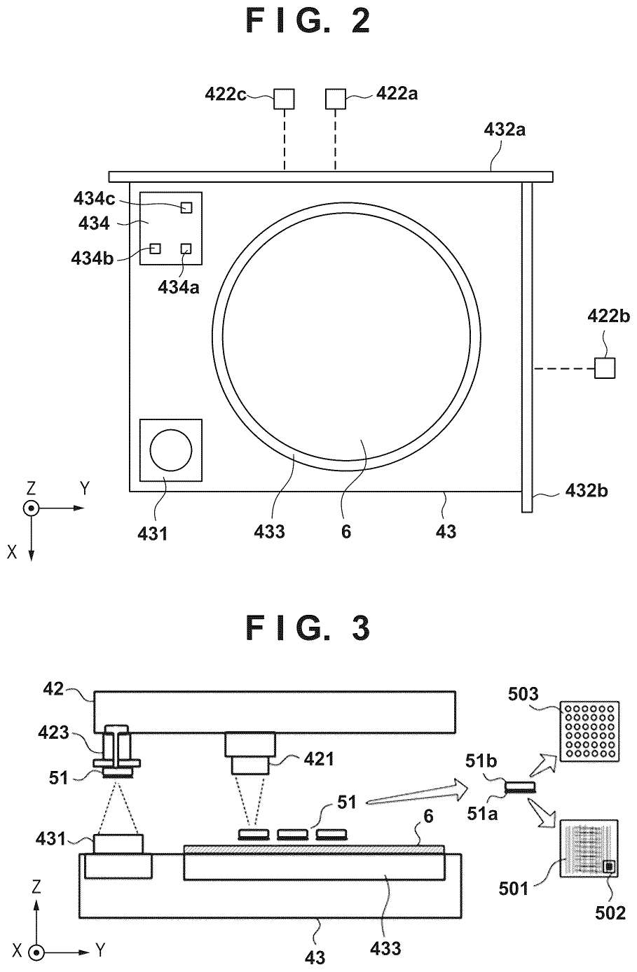

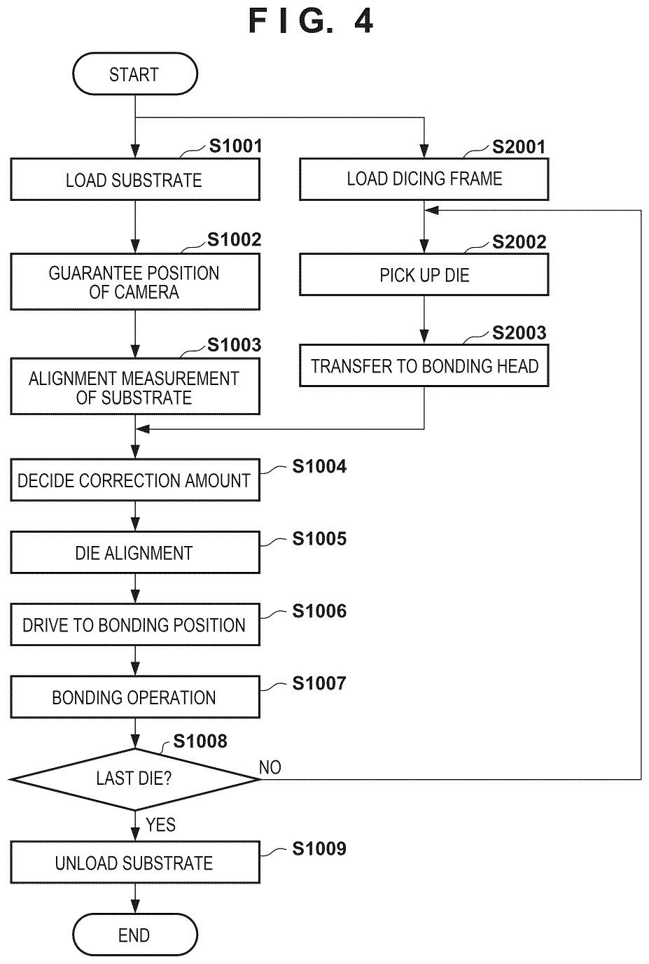

A bonding method in the bonding apparatus BD according to the embodiment will be explained below with reference to FIGS. 3, 4, 5A, and 5B. FIG. 3 is a view schematically showing the bonding method. FIG. 4 is a flowchart illustrating the bonding method. The die 51 has a bonding surface 51a, and a non-bonding surface 51b opposite to the bonding surface 51a. The bonding surface 51a can have, for example, an element pattern 501 and an alignment mark 502. The non-bonding surface 51b can have, for example, a through via array pattern 503.

In step S1001, the controller 441 controls a substrate conveyance apparatus (not shown) to load the substrate 6 serving as the first member into the bonding apparatus BD. If a foreign matter attaches to the bonding surface 51a of the die 51, a bonding failure may occur, so the inside of the bonding apparatus BD can be kept as, for example, a clean space of about class 1. To keep the cleanliness high, even the substrate 6 is contained in a container such as a FOUP in which the closeness and the cleanliness can be kept high, and loaded into the bonding apparatus BD. To increase the cleanliness, the substrate 6 may be cleaned in the bonding apparatus BD after loaded into the bonding apparatus BD. Preprocessing for bonding may also be executed on the substrate 6. For example, when bonding is performed using an adhesive, the adhesive can be applied to the substrate 6. When bonding is performed by hybrid bonding, processing of activating the surface of the substrate 6 can be executed. A pre-alignment unit (not shown) can perform adjustment of the rotational direction of the substrate 6 based on a notch or orientation flat formed on the substrate 6, and rough positioning of the substrate 6 based on the outer shape of the substrate 6. After that, the substrate 6 can be held by the substrate chuck 433 on the substrate stage 43.

In step S1002, the substrate stage 43 can be driven based on a command value decided so that the mark formed on the substrate observation camera 421 (first camera) is arranged at a specific position (for example, the center) of the field of view of the die observation camera 431 (second camera) on the substrate stage 43. Next, the controller 441 can measure the position of the mark on the substrate observation camera 421 using the die observation camera 431. Next, the controller 441 can decide, based on the command value given for driving of the substrate stage 43 and the position of the mark measured using the die observation camera 431, a correction amount for correcting the command value. Thus, by measuring the position of the substrate observation camera 421 and that of the die observation camera 431 at high precision, the relative position between the cameras can be decided at high precision. Step S1002 may be executed before step S1001. It may be changed to execute step S1002 for each die or each substrate.

In step S1003, the controller 441 can execute measurement of the mounting position of the substrate 6, that is, alignment measurement using the substrate observation camera 421. Focus adjustment of the substrate observation camera 421 may be performed by a focus adjustment mechanism provided inside the substrate observation camera 421 or by Z-driving the substrate 6 by the Z-driving mechanism of the substrate stage 43. Alignment measurement is performed by measuring an alignment mark formed in advance on the substrate 6. When no alignment mark is formed on the substrate 6, alignment measurement is performed by measuring a feature point whose position can be specified. The controller 441 can measure the position of the feature point by measuring the image position of the projected feature point with respect to the center of an image obtained by image capturing by the substrate observation camera 421.

To perform high-precision measurement of the position of a mark or a feature point with respect to the reference point of the bonding apparatus BD, a mark formed on the reference plate 434 is made to fall within the field of view of the substrate observation camera 421, and then the position of the mark on the reference plate 434 may be measured by the substrate observation camera 421. An offset amount with respect to the measurement result of the mark or the feature point measured by the substrate observation camera 421 may be decided based on the driving position of the substrate stage 43 at that time and the mark position measured by the substrate observation camera 421. This can measure the position of the mark or the feature point with respect to the reference point of the bonding apparatus BD at high precision. Here, the reference point of the bonding apparatus BD is often a specific mark position of a reference plate in general, but may be another place as long as the position can serve as a reference.

Since the measurement range of the interferometer 442 in the rotational direction is narrow, the amount of rotation that is correctable by the substrate stage 43 is small. Therefore, when the amount of rotation of the substrate 6 is large, it is desirable to correct the rotation and hold again the substrate 6. When the substrate 6 is held again, the mounting position of the substrate 6 needs to be measured again. During this process, the surface position of the substrate 6 is desirably measured using a height measurement unit (not shown) that measures the surface position of the bonding surface of the substrate 6. This is because the thickness of the substrate 6 varies, and the position of the surface of the substrate 6 is important in managing the gap between the substrate 6 (first member) and the die 51 (second member) at high precision in the bonding operation.

Since the origin position, magnification, X- and Y-axis directions (rotations), and orthogonality of the substrate stage 43 are guaranteed using the reference plate 434, the position of the mounted substrate 6 with respect to the origin position, X-axis, and Y-axis of the substrate stage 43 is measured. On the substrate 6, semiconductor devices serving as bonding target locations are repetitively arranged in a predetermined cycle. Since a plurality of layers are positioned and manufactured at high precision by a semiconductor manufacturing apparatus, these semiconductor devices are generally repetitively arrayed in a cycle of nano-level precision. Therefore, in this alignment measurement of the substrate, all bonding target locations at which semiconductor devices are formed need not be measured. For example, array information of semiconductor devices may be input in advance, the positions of semiconductor devices (feature points thereof), the number of which is, for example, three or more that is smaller than the number of bonding target locations, may be measured, and statistical processing may be executed. Based on the result of the statistical processing, the origin position of the repetitive array of bonding target locations, the amounts of rotation in the X-and Y-axis directions, the orthogonality, and the magnification error of the repetitive cycle can be decided.

The substrate chuck 433 desirably includes a mechanism that adjusts the temperature of the substrate 6. This is because the thermal expansion coefficient of a silicon substrate is 3 ppm/° C, and if the temperature of a 300-mm substrate rises by 1° C., the position moves by 150 mm×0.000003=0.00045 mm=450 nm at the outermost periphery. If the bonding position moves after alignment measurement of the substrate 6, bonding cannot be performed at high positional precision. Hence, it is desirable to adjust the temperature of the substrate 6 and stabilize it within 0.1° C. or less.

Note that when the first member is an interposer in which wiring paths are formed, not the array of semiconductor devices but the array of repetitively formed wiring paths is measured. For a substrate or panel having no pattern, no alignment measurement of the substrate is executed.

Next, processing associated with the second member, which is executed in parallel with steps S1001 to S1003, will be explained. In step S2001, a dicing frame can be loaded. The dicing frame can have a dicing tape on which dies individually divided by a dicer are arrayed. If a foreign matter attaches to the bonding surface, a bonding failure may occur, and thus the dicing frame can be transported in a container in which the closeness and the cleanliness are kept high. To increase the cleanliness, dies on the dicing frame may be cleaned in the bonding apparatus BD. The rotational direction and shift position of the dicing frame are roughly positioned by a pre-alignment unit (not shown) based on the outer shape of the dicing frame.

In step S2002, the die 51 can be picked up. The controller 441 can move the pickup head 31 and the release head 32 to the position of the die 51 to be picked up. While the pickup head 31 sucks the die 51, the release head 32 peels the die 51 and the dicing tape, and thus the pickup head 31 can pick up the die 51.

In step S2003, the controller 441 controls the pickup head 31 to transfer the die 51 to the bonding head 423. The bonding head 423 can hold the die 51 by suction by the suction unit 424. When the pickup head 31 picks up the die 51 in step S2002, the semiconductor device surface is on the pickup head 31 side. However, the bonding head 423 can hold the die 51 so that the semiconductor device surface is on a side opposite to the bonding head 423. The transfer can be performed by moving the pickup head 31 to the position of the bonding head 423. Alternatively, the transfer may be performed by relaying the die 51 by one or more holders arranged between the pickup head 31 and the bonding head 423. Pre-processing for bonding can be executed during the transfer. The pre-processing can be die cleaning processing. For bonding using an adhesive, application of the adhesive can be performed as the pre-processing. For hybrid bonding, processing of activating the surface can be executed as the pre-processing.

As a result, the substrate 6 serving as the first member and the die 51 serving as the second member are held by the first holder and the second holder, respectively.

In step S1004, based on the operation history of the bonding apparatus BD and the above-described characteristic formula, the controller 441 can decide a correction amount for correcting the position of the die 51 detected using the die observation camera 431 serving as the second camera. A practical example of a decision method for correction will be described later.

In step S1005, the controller 441 can measure the position of the die 51 held by the bonding head 423 using the die observation camera 431. More specifically, the controller 441 can drive the substrate stage 43 so that the feature point of the die 51 falls within the field of view of the die observation camera 431. The feature point can be an element pattern or an alignment mark on the die bonding surface 51a. Alternatively, all or part of the outer dimensional shape of the die 51 may be handled as a feature point. Focus adjustment can be performed by, for example, the focus adjustment mechanism of the die observation camera 431. Alternatively, focus adjustment may be performed by Z-driving the die 51 by the Z-driving mechanism of the bonding head 423. Alternatively, focus adjustment may be performed by Z-driving the die observation camera 431 by the Z-driving mechanism of the substrate stage 43 on which the die observation camera 431 is mounted. Since a scribe line on which an alignment mark used for alignment is formed is removed from a die by dicing in a semiconductor manufacturing process, an alignment mark for alignment is not arranged on the die in many cases. Hence, it is useful to measure, as a feature point, the termination of the array of pads or bumps arranged on the die bonding surface 51a, a region where the array is aperiodic and a position can be specified, or the outer shape of the die 51.

The controller 441 can measure, as the position of the die 51, the relative position of a feature point of the die 51 with respect to the center of an image captured by the die observation camera 431. At this time, the controller 441 may measure the amount of rotation of the die 51 by measuring the positions of a plurality of feature points of the die 51 with respect to the center of the image captured by the die observation camera 431. The positions of a plurality of feature points may be measured while driving the substrate stage 43. Alternatively, the field of view of the die observation camera 431 may be widened to measure the positions of a plurality of feature points within the field of view.

The rotation of the die 51 can be corrected by the rotation of the substrate stage 43 at the time of bonding. However, the measurement range of the interferometer in the rotational direction is narrow. Thus, when the amount of rotation of the die 51 is large, it is desirable to correct the rotation and hold again the die 51. When the die 51 is held again, the position of the die 51 needs to be measured again. During this process, the surface position of the die 51 is desirably measured using a height measurement unit (not shown) that measures the surface position of the bonding surface 51a of the die 51. This is because the thickness of the die 51 varies, and the position of the surface of the die 51 is important in managing the gap between the die 51 and the substrate 6 at high precision in the bonding operation. It is also desirable to measure the heights of a plurality of positions on the die 51 and adjust the posture of the die or substrate by a tilt mechanism (not shown) at the time of bonding. The tilt mechanism can be provided in any of the substrate stage 43, the substrate chuck 433, and the bonding head 423. In this process, the position of the feature point of the measured die 51 and the outer dimensional information of the die itself are associated. In the association, the outer shape of the die 51 and the position of an element pattern or alignment mark on the die bonding surface 51a are associated. The controller 441 stores the associated information in a predetermined storage device inside or outside the apparatus.

In this fashion, in step S1005, the controller 441 can measure an element pattern or alignment mark on the die bonding surface 51a, which is a feature point of the die 51, and all or part of the outer shape of the die 51. Thereafter, the position of the feature point of the die 51 and the outer dimensional information of the die 51 itself are associated, and the information is stored. Instead of performing such measurement in this process, pieces of information about a die to be loaded may be input from outside the bonding apparatus and stored in the bonding apparatus.

In step S1006, the controller 441 can control, based on the output of the substrate observation camera 421, the output of the die observation camera 431, and the correction amount decided in step S1004, the positioning mechanism PS so as to position the die 51 at the bonding target location of the substrate 6. As described above, in step S1004, the correction amount can be decided based on the operation history of the bonding apparatus BD. Therefore, it may be understood that the controller 441 controls, based on the output of the substrate observation camera 421, the output of the die observation camera 431, and the operation history of the bonding apparatus BD, the positioning mechanism PS so as to position the die 51 at the bonding target location of the substrate 6. Note that the controller 441 can position the substrate stage 43 at high precision by measuring the position of the substrate stage 43 by the interferometer 422 and feedback-controlling the substrate stage 43 in real time.

In step S1007, the controller 441 can control the bonding operation of bonding the die 51 to the bonding target location of the substrate 6. By controlling the driving mechanism 450 serving as a relative driving mechanism, the controller 441 can perform the approximating operation of moving the bonding head 423 and the substrate stage 43 close to each other so as to bring the die 51 into contact with the bonding target location of the substrate 6 and bond it. After that, the controller 441 can control the driving mechanism 450 to perform the separating operation of moving the bonding head 423 and the substrate stage 43 away from each other.

In step S1008, the controller 441 confirms whether the bonding operation has been performed on all the dies 51 that should be bonded to the substrate 6. In general, several tens or several hundreds of semiconductor devices are formed on one substrate, and dies are bonded to the respective semiconductor devices, so die bonding is repeated a plurality of times. If the bonding operation has not been performed on all the dies 51, the process returns to step S2002.

Note that the determination processing in step S1008 is performed after confirming whether the bonding operation in step S1007 has been performed. However, it is also possible to perform the determination processing in step S1008 before the bonding operation in step S1007, and execute the die pickup operation in step S2002 in parallel with steps S1005 to S1007. When a plurality of types of dies are bonded to one semiconductor device, bonding of dies of one type ends for all semiconductor devices on one substrate, and then bonding of dies of the next type starts. In this case, dies of the next type are picked up in step S2002. At this time, a necessary process such as the loading operation of a dicing frame on which dies of the next type are mounted is executed.

If the bonding operation ends for all the dies 51, the controller 441 can control the substrate conveyance apparatus (not shown) to unload the substrate 6 from the bonding apparatus in step S1009. The unloaded substrate may be returned to the original container such as a FOUP or to another container. In general, the substrate thickness has changed, the gap between substrates needs to be widened compared to substrates before bonding, and thus the unloaded substrate is returned to another container.

The bonding sequence for one substrate has been described above. This operation is repeated respectively by a necessary number of substrates.

Note that the number of dies 51 on the dicing frame and that of semiconductor devices on the substrate 6 to which the dies 51 are bonded are generally different, so loading of the substrate 6 and that of the dicing frame are not synchronized. If the dies 51 on the dicing frame run out during the bonding operation for one substrate 6, the next dicing frame is loaded. If the dies 51 on the dicing frame remain even after the end of bonding for one substrate 6, they are used for bonding for the next substrate 6.

A practical example of the processing of deciding the correction amount based on the operation history of the bonding apparatus BD in step S1004 will be described below. The characteristic formula representing the relationship between the operation history of the bonding apparatus BD and the change amount of the relative position between the reference plate 434 and the die observation camera 431 (second camera) can be a formula that gives a correction amount (the change amount of the relative position between the reference plate 434 and the die observation camera 431 (second camera)). For example, the characteristic formula can be given by:

$$( Cx , Cy ) = ( Iox , Ioy ) \times ( 1 - 1 / exp ( t / K ) ) \qquad ( 1 )$$

wherein (Cx, Cy) represents the change amount of the relative position between the reference plate 434 and the die observation camera 431 (second camera) in the X and Y directions. (Iox, Ioy) represents the change amount of the relative position between the reference plate 434 and the die observation camera 431 (second camera) in the X and Y directions at the time of thermal equilibrium. t represents a variable obtained by indexing the operation history of the bonding apparatus BD. t can represent, for example, an index value indicating the history of the power supply state of the die observation camera 431 or an elapsed time since power-on of the die observation camera 431. Alternatively, t can represent the number of times of image capturing by the die observation camera 431 after power-on of the die observation camera 431. K can correspond to, for example, a time constant.

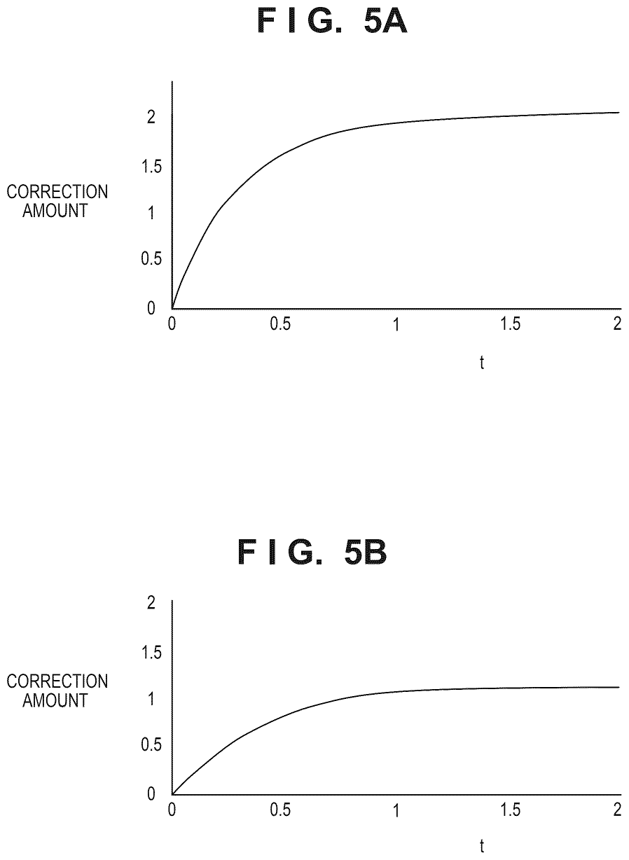

FIG. 5A visually shows an example of a characteristic formula that gives a correction amount C. In the example shown in FIG. 5A, the abscissa represents the variable obtained by indexing the operation history of the bonding apparatus BD, and more specifically, an elapsed time since power-on of the die observation camera 431. Note that the elapsed time since power-on of the die observation camera 431 is an elapsed time from last power-on of the die observation camera 431 until now. In the example shown in FIG. 5A, the ordinate represents the change amount of the relative position between the reference plate 434 and the die observation camera 431 (second camera) in the X direction, that is, a correction amount Cx. The curve of the change amount of the relative position between the reference plate 434 and the die observation camera 431 (second camera) in the Y direction, that is, the curve of a correction amount Cy can be proportional to, for example, the correction amount Cx.

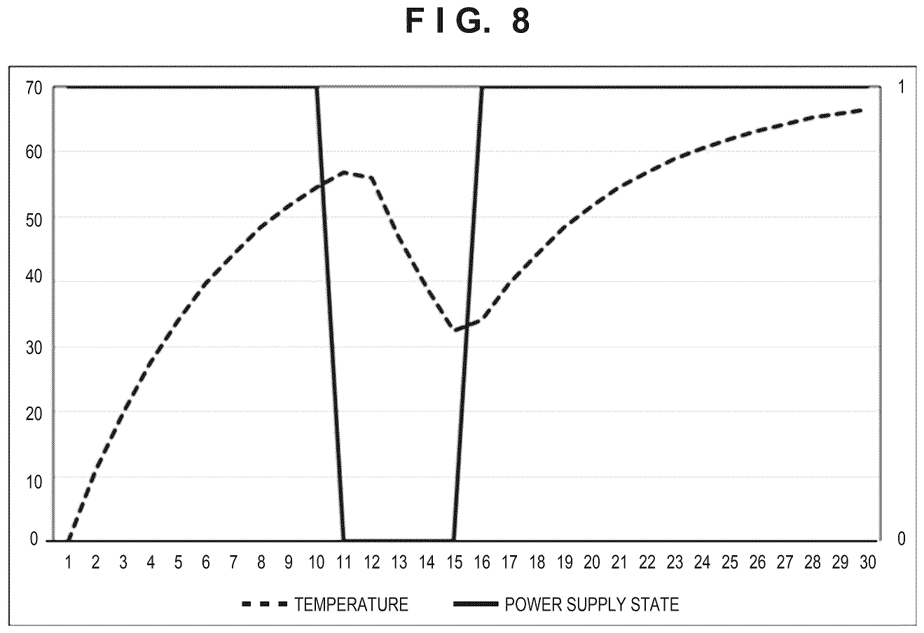

FIG. 8 exemplifies the relationship between a change of the power supply state of the die observation camera 431 and a change of the temperature of the die observation camera 431. In FIG. 8, the abscissa represents a lapse of time. In FIG. 8, a solid line indicates the power supply state of the die observation camera 431. When the value on the ordinate on the right is 1, the power is ON, and when the value on the ordinate on the right is 0, the power is OFF. In FIG. 8, a dotted line indicates the change amount of the temperature from the reference temperature of the die observation camera 431. In a case where the time during which the power of the die observation camera 431 is OFF is short and the die observation camera 431 is powered on while the temperature does not lower to the reference temperature of the die observation camera 431, t in equation (1) is replaced by t+α. α represents an offset value corresponding to the difference between the current temperature of the die observation camera 431 and the reference temperature. α can be decided in advance by an experiment or the like.

In the above example, the correction amounts (shift correction amounts) in the X and Y directions are decided as the correction amount, but other components such as magnification and/or rotation may also be corrected.

### Second Embodiment

The second embodiment will be described below. Matters not mentioned in the second embodiment can comply with the first embodiment. In the second embodiment, when calculating a correction amount in accordance with equation (1), a coefficient considering the position of a substrate stage 43 is used. A measurement value of an interferometer 422 in a space where the substrate stage 43 is arranged changes in accordance with a change of the temperature. To cope with this, the temperature in the space can be adjusted by flowing temperature-regulated air at a constant flow rate. However, the flow of air changes the temperature of an object on the substrate stage 43. This causes a change of the temperature of a die observation camera 431, resulting in a change of the relative position among a bar mirror 432, a reference plate 434, and the die observation camera 431. The change of the relative position causes an error in a measurement result of the position of a die 51, thereby disabling high-precision bonding. Depending on how temperature-regulated air flows, the change amount of the position of the die observation camera 431 may change, and a time constant K and a change amount Io at the time of thermal equilibrium in equation (1) also change depending on the position of the substrate stage 43. Therefore, by setting the time constant K and the change amount Io at the time of thermal equilibrium in equation (1) for each position of the substrate stage 43, and performing prediction, it is possible to calculate a more accurate correction amount. More specifically, the correction amount is preferably calculated in accordance with equation (1) using a coefficient corresponding to the position of the substrate stage 43.

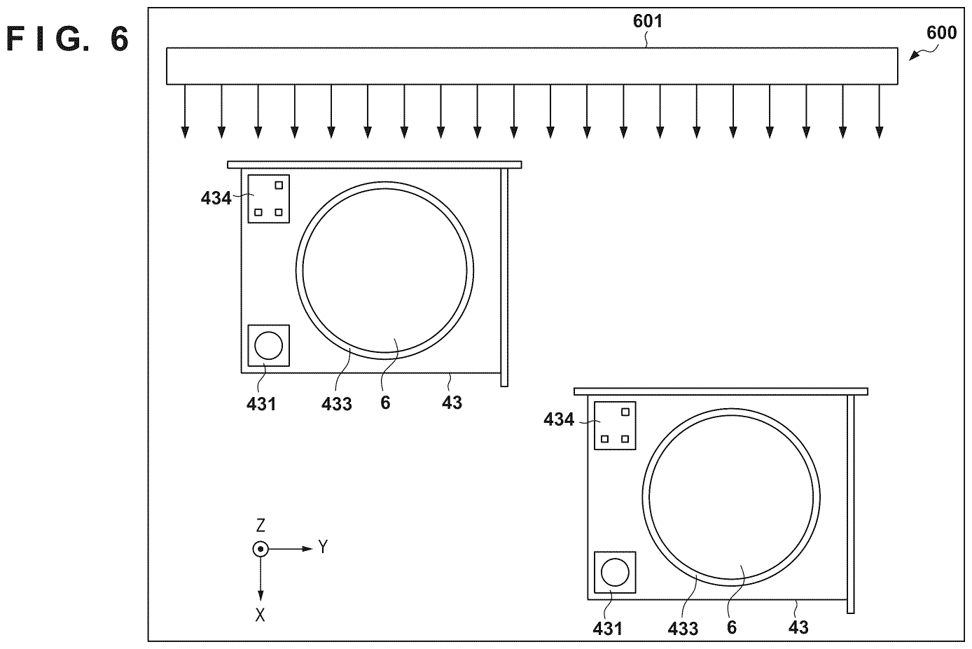

For example, the position of the substrate stage 43 is different between the time of executing step S1003 and the time of executing step S1005. As schematically shown in FIG. 6, a bonding apparatus BD can include a temperature regulator 600 that supplies temperature-regulated air to a space where the substrate stage 43 can move. The temperature of air supplied from a blowing outlet 601 of the temperature regulator 600 to the substrate stage 43 can change depending on the position of the substrate stage 43. For example, the lower right portion of FIG. 6 indicates the position of the substrate stage 43 at the time of executing step S1003, and the upper left portion of FIG. 6 indicates the position of the substrate stage 43 at the time of executing step S1005. When the distance from the blowing outlet 601 changes depending on the position of the substrate stage 43, the influence on the temperature of the die observation camera 431 can also change. That is, since the change amount of the position of the die observation camera 431 changes depending on the position of the substrate stage 43, the correction amount is preferably calculated using the coefficient of equation (1) decided in accordance with it. That is, based on the output of a substrate observation camera 421, the output of the die observation camera 431, and the operation history of the bonding apparatus BD as well as the position of the substrate stage 43, a controller 441 can control a positioning mechanism PS so as to position the die 51 at a bonding target location of a substrate 6.

FIG. 5A exemplifies the correction amount in a state in which the substrate stage 43 is positioned at a first position, and FIG. 5B exemplifies the correction amount in a state in which the substrate stage 43 is positioned at a second position different from the first position.

### Third Embodiment

The third embodiment will be described below. Matters not mentioned in the third embodiment can comply with the first or second embodiment. A correction amount (Cx, Cy) for performing stricter correction can depend on the stop position and the stop time of a substrate stage 43. Thus, in the third embodiment, the stop position and the stop time of the substrate stage 43 are taken into account.

In bonding processing, the substrate stage 43 stops in a given process but the substrate stage 43 can move to a predetermined position at the start of the next process. At this time, the temperature of a die observation camera 431 changes depending on the stop position and the stop time of the substrate stage 43. As a result, the die observation camera 431 is also influenced by the history of the stop position and the stop time of the substrate stage 43. Thus, by setting a time constant K and a change amount (Iox, Ioy) at the time of thermal equilibrium in equation (1) for each stop position of the substrate stage 43 in accordance with the stop time, it is possible to decide the correction amount (Cx, Cy) more strictly. That is, based on the outputs of the cameras 421 and 431 and the operation history of a bonding apparatus BD as well as the stop position and the stop time of the substrate stage 43, a controller 441 can control a positioning mechanism PS so as to position a die 51 to a bonding target location of a substrate 6.

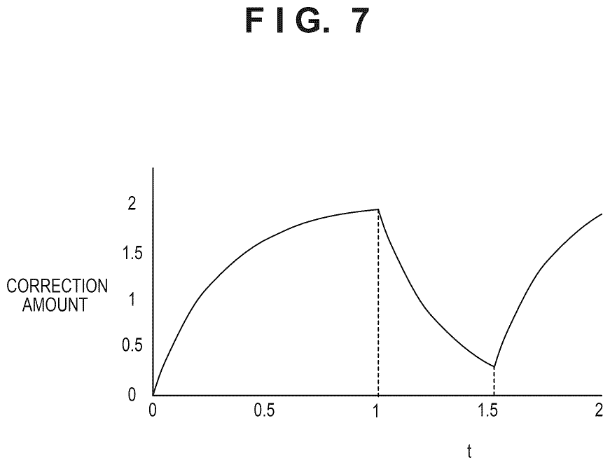

More specifically, for each process of a bonding method including steps S1001 to S1007 of FIG. 4, the coefficient of equation (1) is preferably set in accordance with the stop position and the stop time of the substrate stage 43. For example, FIG. 7 exemplifies a change of the correction amount when the operation of the bonding apparatus BD is stopped for 30 minutes during execution of step S1002 after executing the bonding method shown in FIG. 4 for 1 hour and then the operation of the bonding apparatus BD is resumed thereafter. In FIG. 7, from t=0 to t=1, the correction amount while executing the bonding method shown in FIG. 4 is shown. In FIG. 7, from t=1 to t=1.5, the correction amount while the operation of the bonding apparatus BD is stopped is shown. In FIG. 7, from t=1.5 to t=2, the correction amount after the bonding method shown in FIG. 4 is restarted is shown.

### Embodiment of Article Manufacturing Method

A method of manufacturing an article (a semiconductor IC element, a liquid crystal display element, a MEMS, or the like) using the above-described bonding apparatus will be explained. The article manufacturing method according to the embodiment of the present disclosure is suitable for manufacturing an article, for example, a microdevice such as a semiconductor device or an element having a fine structure. The article manufacturing method according to the embodiment can include a bonding step of forming a bonded object by bonding a second member to a first member using the above-described bonding apparatus, and a processing step of obtaining an article by processing the bonded object formed in the bonding step. Further, the manufacturing method includes other known processes (probing, dicing, bonding, packaging, and the like). The article manufacturing method according to the embodiment is advantageous in at least one of the performance, quality, productivity, and production cost of the article, as compared to conventional methods.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-007982, filed Jan. 20, 2025, which is hereby incorporated by reference herein in its entirety.

What is claimed is:

1. A bonding apparatus for bonding a second member to a first member, comprising:
a first holder configured to hold the first member;
a second holder configured to hold the second member;
a positioning mechanism configured to adjust a relative position between the first holder and the second holder;
a first camera configured to capture the first member;
a second camera held by the first holder and configured to capture the second member; and
a controller configured to control, based on an output of the first camera, an output of the second camera, and an operation history of the bonding apparatus, the positioning mechanism so as to position the second member to a bonding target location of the first member.

2. The apparatus according to claim 1, further comprising a measuring device configured to measure a position of the first holder,
wherein the positioning mechanism feedback-controls the first holder based on an output of the measuring device.

3. The apparatus according to claim 1, further comprising a temperature regulator configured to supply temperature-regulated air to a space where the first holder can move,
wherein the controller controls, further based on a position of the first holder, the positioning mechanism so as to position the second member to the bonding target location of the first member.

4. The apparatus according to claim 1, further comprising a temperature regulator configured to supply temperature-regulated air to a space where the first holder can move,
wherein the controller controls, further based on a stop position and a stop time of the first holder, the positioning mechanism so as to position the second member to the bonding target location of the first member.

5. The apparatus according to claim 1, wherein the operation history is an elapsed time since power-on of the bonding apparatus.

6. The apparatus according to claim 1, wherein the operation history is a history of power supply state of the second camera.

7. The apparatus according to claim 1, wherein the operation history is an elapsed time since power-on of the second camera.

8. The apparatus according to claim 1, wherein the operation history is the number of times of image capturing by the second camera after power-on of the second camera.

9. The apparatus according to claim 1, wherein the controller corrects, based on the operation history of the bonding apparatus, a position of the second member obtained based on the output of the second camera.

10. The apparatus according to claim 2, wherein
the measuring device includes a measured portion provided in the first holder, and
the second camera is provided at a position apart from the measured portion.

11. The apparatus according to claim 10, wherein
the first holder is provided with a reference plate having a mark, and the controller obtains a relationship between the operation history of the bonding apparatus and a change of a relative position between the reference plate and the second camera.

12. The apparatus according to claim 11, wherein the controller obtains the relative position by measuring a position of the mark of the reference plate and a position of the second camera using the first camera.

13. The apparatus according to claim 1, further comprising a support configured to support the second holder and the first camera.

14. A bonding method of bonding a second member to a first member in a bonding apparatus including a first holder configured to hold the first member, a second holder configured to hold the second member, a positioning mechanism configured to adjust a relative position between the first holder and the second holder, a first camera configured to capture the first member, and a second camera held by the first holder and configured to capture the second member, the method comprising:
obtaining an operation history of the bonding apparatus; and
controlling, based on an output of the first camera, an output of the second camera, and the operation history, the positioning mechanism so as to position the second member to a bonding target location of the first member.

15. An article manufacturing method comprising:
forming a bonded object by bonding a second member to a first member; and
obtaining an article by processing the bonded object,
wherein the forming of the bonded object is performed in a bonding apparatus including a first holder configured to hold the first member, a second holder configured to hold the second member, a positioning mechanism configured to adjust a relative position between the first holder and the second holder, a first camera configured to capture the first member, and a second camera held by the first holder and configured to capture the second member, and the forming of the bonded object comprises:
obtaining an operation history of the bonding apparatus; and
controlling, based on an output of the first camera, an output of the second camera, and the operation history, the positioning mechanism so as to position the second member to a bonding target location of the first member.
